(19) United States
(12) Patent Application Publication
(10) Pub. No.: US 2026/0088781 A1
(43) Pub. Date: Mar. 26, 2026

(54) Semiconductor layout pattern and radio frequency circuit layout pattern

(71) Applicant: UNITED MICROELECTRONICS CORP., Hsin-Chu City (TW)

(72) Inventors: Chien-Yi Lee, Pingtung County (TW); Chih-Hsien Huang, Yunlin County (TW); Yi-Chin Li, Hualien County (TW); Chun-Liang Cheng, Hsinchu City (TW); Sheng-Huei Dai, Taitung County (TW)

(73) Assignee: UNITED MICROELECTRONICS CORP., Hsin-Chu City (TW)

(21) Appl. No.: 18/936,976

(22) Filed: Nov. 4, 2024

(30) Foreign Application Priority Data
Sep. 26, 2024 (TW) 113136581

(51) Int. Cl. H03F 3/24; H03F 1/22

(52) U.S. Cl. CPC H03F 3/245; H03F 1/223; H03F 2200/451

(57) ABSTRACT

The invention provides a semiconductor layout pattern, which includes a substrate, an active area is defined on the substrate, a plurality of gate structures are located in the active area, and a plurality of doped regions are located in the active area, wherein the plurality of gate structures and doped regions contained in the active area form a first amplifier and a second amplifier, the first amplifier and the second amplifier are connected in series with each other, and a drain doped region of the first amplifier and a source doped region of the second amplifier share the same doped region. The invention has the advantages of saving element space and improving the efficiency of the amplifier.

### BACKGROUND OF THE INVENTION

### 1. Field of the Invention

The invention relates to the field of semiconductors, in particular to a semiconductor layout pattern suitable for power amplifiers, which has the advantages of reducing space and improving efficiency.

### 2. Description of the Prior Art

Power amplifier is an important component in RF power transmission. Its main function is to amplify and output signals. It is usually designed at the front end of antenna radiator, and it is also the most power-consuming component in the whole RF front-end circuit.

Power amplifiers are mainly used in electronic products or devices that need bandwidth, such as mobile phones, tablet computers, WiMAX, Wi-Fi, Bluetooth, RFID readers, satellite communications and other network communication products.

Two-stage amplifier is one of the power amplifiers, which is an amplifier circuit composed of two amplifiers connected in series. Its main purpose is to achieve higher overall gain through multi-stage amplification, and at the same time improve the frequency response, distortion and other problems that may exist in single-stage amplifier.

Cascade amplifier (or Cascode amplifier) is a two-stage amplifier consisting of a common source (or emitter) connected in series with a common gate (or common base). Compared with single-stage amplifier, the combination of common source and common gate can achieve the following characteristics: better input/output shielding characteristics, higher input impedance, higher output impedance and wider bandwidth. In modern circuits, cascade amplifiers may be composed of two different transistors (bipolar junction transistors and field effect transistors). Because the cascode has better input/output isolation characteristics and less direct coupling between input and output points, it can weaken the influence caused by Miller effect and thus obtain greater bandwidth. At present, there is still room for improvement in power amplifiers, for example, its layout pattern occupies a large area, which is not conducive to the miniaturization of products.

### SUMMARY OF THE INVENTION

The invention provides a semiconductor layout pattern, which comprises a substrate, wherein an active area is defined on the substrate, and a plurality of gate structures are located in the active area, wherein each gate structure is arranged in parallel with each other along a first direction, and a plurality of doped regions are located in the substrate on both sides of each gate structure, wherein the plurality of gate structures contained in the active area include a first gate structure and a second gate structure, a plurality of doped regions contained in the active area include a first source doped region, a first drain doped region, a second source doped region and a second drain doped region, wherein the first gate structure, the first source doped region and the first drain doped region constitute a first amplifier, and the second gate structure, the second source doped region and the second drain doped region constitute a second amplifier, and the first drain doped region and the second source doped region include a same doped region among the plurality of doped regions, and the same doped region is defined as a common doped region.

The invention also provides a radio frequency circuit layout pattern, which comprises a substrate with an active area defined thereon, a plurality of gate structures located in the active area, wherein the gate structures are arranged in parallel with each other along a first direction, a plurality of doped regions located in the active area, and each doped region is located in the substrate on both sides of each gate structure, wherein the plurality of gate structures and the plurality of doped regions included in the active area constitute a first amplifier and a second amplifier, wherein a drain of the first amplifier and a source of the second amplifier are connected with each other, and both the drain of the first amplifier and the source of the second amplifier are located on a common doped region.

The present invention is characterized in that, in order to save element space and reduce the influence of wire impedance when making the layout pattern of two-stage amplifier, the two amplifiers are made in the same active area, so that all the two amplifiers included in the two-stage amplifier can share a part of the doped region, that is to say, there is no shallow trench isolation between the regions where the two amplifiers are located. Under the concept of the invention, the device size can be effectively reduced, and the efficiency of the amplifier can also be improved because the influence of wire impedance is reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 shows a circuit diagram of a cascade amplifier.

FIG. 2 is a schematic diagram showing the arrangement of a first amplifier and a second amplifier of a cascade amplifier according to two different embodiments.

FIG. 3 shows the arrangement of the first amplifier and the second amplifier in the active area according to some different embodiments of the present invention, wherein, Figures (a), (b), (c), (d) and (e) in FIG. 3 respectively show five different arrangements.

FIG. 4, FIG. 5 and FIG. 6 respectively show layout diagrams of several two-stage amplifiers according to different embodiments of the present invention.

FIG. 7 is a schematic diagram showing the layout of RF circuit patterns according to an embodiment of the present invention.

FIG. 8 shows a circuit diagram of a stacked MOS metal oxide semiconductor transistor (stacked MOS).

FIG. 9 is a schematic layout diagram of stacked MOS metal oxide semiconductor transistors according to an embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about”or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

As mentioned in the previous paragraph, the two-stage amplifier belongs to a kind of power amplifier. With different applications, there are various types of two-stage amplifiers, such as the aforementioned cascade amplifier, or other common two-stage amplifiers, such as stacked MOS, Gilbert mixer, RF switch and active inductor, all belong to the application of two-stage amplifiers. In order to clearly explain the characteristics of this case, the following paragraphs mainly focus on the cascade amplifier, but those skilled in the art can know that the application scope of the present invention also includes other types of two-stage amplifiers other than the cascade amplifier, which will be described here first.

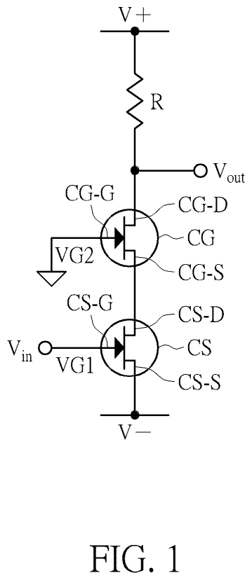

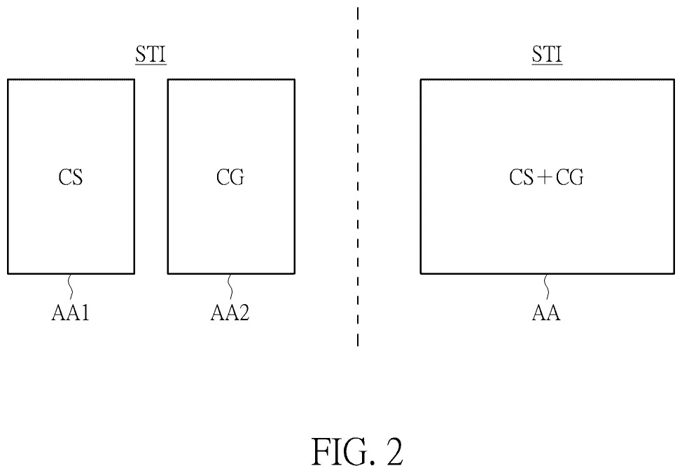

FIG. 1 shows a circuit diagram of a cascade amplifier, and FIG. 2 shows a schematic arrangement of a first amplifier and a second amplifier of the cascade amplifier according to two different embodiments. As shown in FIG. 1, a cascade amplifier includes a first amplifier CS, such as a common source amplifier, and a second amplifier CG, such as a common gate amplifier, wherein the first amplifier CS and the second amplifier CG are connected in series. More specifically, the gate terminal CS-G of the first amplifier CS is connected to an input signal VG1 (or input signal Vin), and the source terminal CS-S of the first amplifier CS is connected to the potential V− or ground. The gate terminal CG-G of the second amplifier CG is connected to a voltage source VG2, the drain terminal CG-D of the second amplifier CG is connected to the output signal Vout, and the drain terminal CS-D of the first amplifier CS is connected to the source terminal CG-S of the second amplifier CG. In addition, the circuit diagram in FIG. 1 also includes a resistor R and a voltage source V+ connected to the circuit. These contents belong to the conventional circuit technology of cascade amplifiers, and do not belong to the key features of the present invention, so they are not repeated here.

It is worth noting that, as shown in FIG. 1, the drain terminal CS-D of the first amplifier CS is connected to the source terminal CG-S of the second amplifier CG. Therefore, when the first amplifier CS and the second amplifier CG are together formed on a substrate (not shown), as shown in the left embodiment of FIG. 2, the left side of FIG. 2 shows a schematic diagram of forming the first amplifier CS and the second amplifier CG side by side on a substrate according to one of the embodiments. The first amplifier CS and the second amplifier CG are respectively formed in two active areas AA1 and AA2, and the two active areas AA1 and AA2 are separated by shallow trench isolation STI. Subsequently, after the first amplifier CS and the second amplifier CG are respectively formed in the active area AA1 and the active area AA2, the two amplifiers are connected in series by elements such as wires, for example, the drain terminal CS-D of the first amplifier CS is connected to the source terminal CG-S of the second amplifier CG. Here, for the sake of simplicity, the layout structures in the first amplifier CS and the second amplifier CG, such as gate structures, source/drain doped regions, contact structures, wires and other elements, are not drawn in FIG. 2. However, those skilled in the art should know that the layout structure should be included in the range of the first amplifier CS and the second amplifier CG shown in FIG. 2.

However, in the embodiment shown on the left of FIG. 2, even though the two active areas AA1 and AA2 (where the first amplifier CS and the second amplifier CG are formed respectively) are as close as possible, there is still a shallow trench isolation STI with a certain width between the active area AA1 and the active area AA2 under the limitation of the process conditions. Therefore, there are two problems. One of them is that the active areas AA1 and AA2 occupy a certain area, and the two active areas AA1 and AA2 are adjacent to each other, which is not conducive to miniaturization of devices. Another problem is that the first amplifier CS and the second amplifier CG need to be connected to each other by wires and other elements, and the wires themselves have a certain impedance. Therefore, when the distance between the active area AA1 and the active area AA2 is far away, the length of the wires will also increase, and the impedance of the whole element will be improved, which is not conducive to the improvement of the amplifier's performance.

Therefore, based on the above problems, the applicant of the present invention proposes another layout and arrangement pattern suitable for power amplifiers. As shown in the right half of FIG. 2, compared with the embodiment shown in the left half of FIG. 2, in this embodiment, the first amplifier CS and the second amplifier CG are formed together in the same active area AA, and the active area AA is surrounded by shallow trench isolation STI. Therefore, since the first amplifier CS and the second amplifier CG share the same active area AA, and shallow trench isolation STI is not included between the first amplifier CS and the second amplifier CG, the area of the whole device can be reduced (because the same active area AA is shared). In addition, because the distance between the first amplifier CS and the second amplifier CG is shortened, the two amplifiers are less affected by the wire impedance after being connected with each other, which is beneficial to improving the efficiency of the amplifiers.

In a word, the concept of the present invention is to make the original two amplifiers CS and CG separated from each other in the same active area AA, thereby achieving the advantages of reducing device space and improving efficiency. Under this concept, according to the different arrangement of the first amplifier CS and the second amplifier CG contained in the active area AA, various different embodiments of the present invention can be formed. Some embodiments will be described in the following paragraphs.

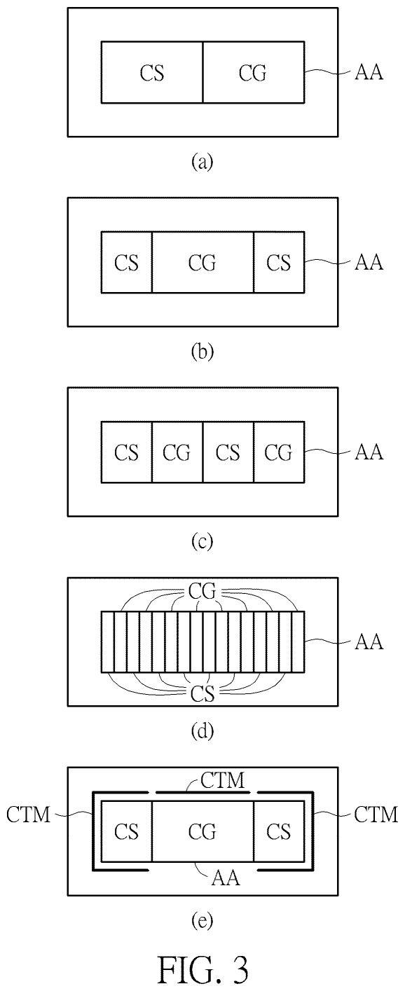

FIG. 3 shows the arrangement of the first amplifier and the second amplifier in the active area according to some different embodiments of the present invention, wherein, Figures (a), (b), (c), (d) and (e) in FIG. 3 respectively show five different arrangements. For the sake of simplicity, the layout structure in the first amplifier CS and the second amplifier CG is not drawn in FIG. 3, but those skilled in the art should know that the layout structure should be included in the range of the first amplifier CS and the second amplifier CG shown in FIG. 3. As shown in Fig. (a), in the active area AA, both the first amplifier CS and the second amplifier CG are side by side with each other. As shown in Fig. (b), a second amplifier CG is located between two first amplifiers CS in the active area AA. As shown in Fig. (c), the first amplifier CS, the second amplifier CG, the first amplifier CS and the second amplifier CG are respectively included from left to right. As shown in Fig. (d), from left to right, a plurality of groups of first amplifiers CS and second amplifiers CG are repeatedly arranged (that is, in the order of first amplifier CS, second amplifier CG, first amplifier CS, second amplifier CG, etc.). As shown in Fig. (e), this embodiment also includes a contact metal layer CTM located at the periphery of the amplifier, and the contact metal layer CTM can connect a plurality of gates (not shown) in the amplifier with each other or connect a plurality of sources/drains in the amplifier with each other. The contact metal layer CTM can be located on at least one side of the amplifier. For example, in Figure (e) of FIG. 3, the contact metal layer CTM is located on the upper side, the lower side and the left and right sides of the first amplifier CS, while another part of the contact metal layer CTM is located on the upper side of the second amplifier CG, but not on the lower side of the second amplifier CG.

It is worth noting that several possible arrangement layouts of the first amplifier and the second amplifier are depicted in FIG. 3, but the present invention is not limited to this. For example, in the various embodiments shown in FIG. 3, it is also possible to exchange the positions of the first amplifier CS and the second amplifier CG. For example, in Figure (a), the first amplifier CS is on the left and the second amplifier CG is on the right, but in fact, the positions of the two amplifiers can also be exchanged (that is, the first amplifier CS is on the right and the second amplifier CG is on the left), which is also within the scope of the present invention. In addition, the arrangement of the contact metal layer CTM shown in Fig. (e) can also be changed according to actual needs, for example, some contact metal layers CTM can be added or deleted at the periphery of the first amplifier CS and the second amplifier CG. All the above variations are within the scope of the present invention.

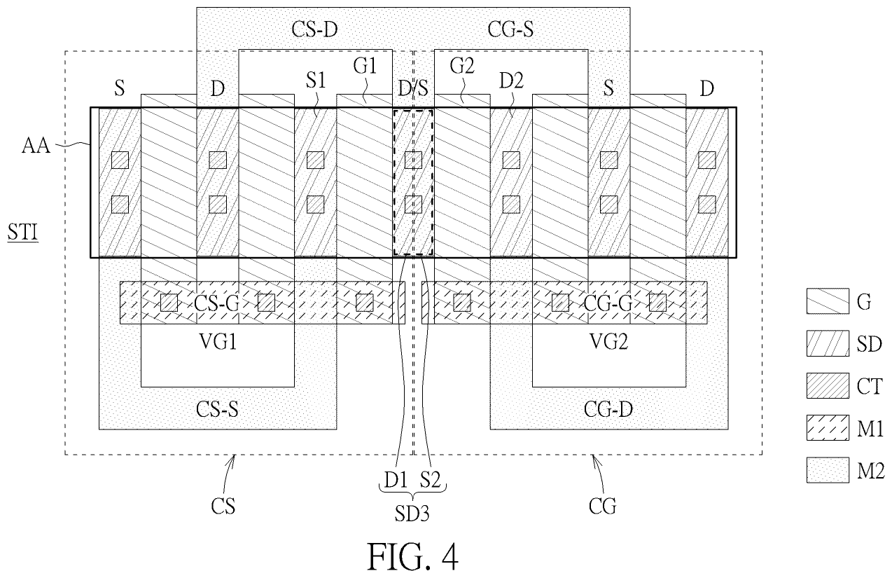

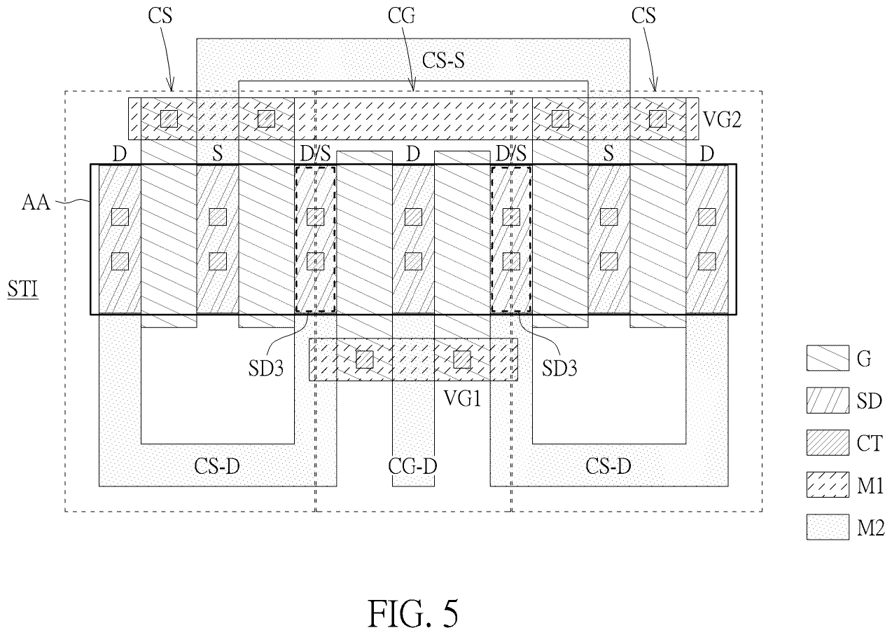

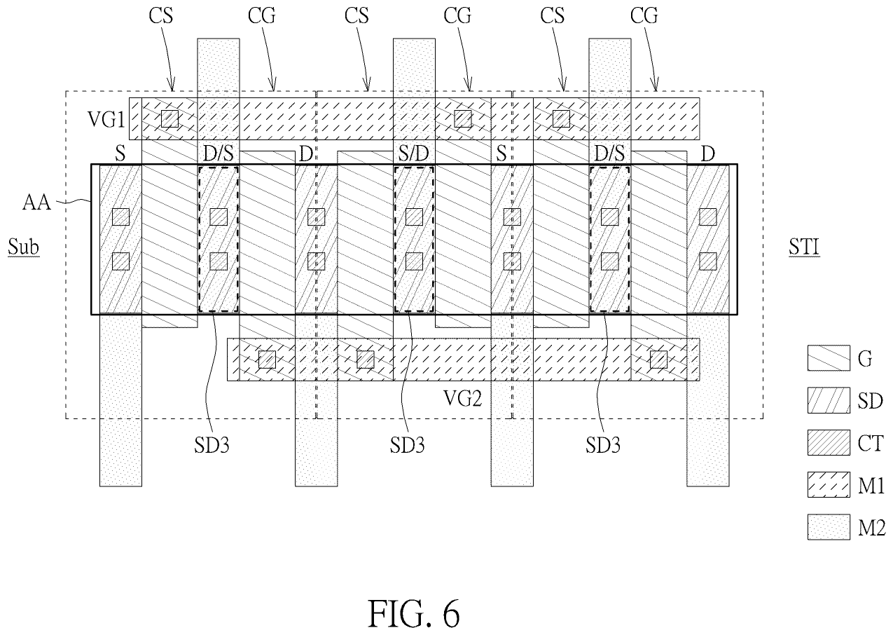

FIG. 4, FIG. 5 and FIG. 6 respectively show layout diagrams of several two-stage amplifiers according to different embodiments of the present invention. The two-stage amplifier shown in FIGS. 4, 5 and 6 takes the cascade amplifier as an example. First, as shown in FIG. 4, an active area AA and a shallow trench isolation STI surrounding the active area AA are defined on a substrate Sub, and then a first amplifier CS and a second amplifier CG are formed in the active area AA. However, according to the different arrangement of the first amplifier CS and the second amplifier CG, many different embodiments can be formed. For example, in FIG. 4, this embodiment is similar to the arrangement shown in Figure (a) of FIG. 3. A first amplifier CS is formed in the left part of the active area AA, and a second amplifier CG is formed in the right part of the active area AA. A plurality of gate structures G are formed in the active area AA as the gates of the first amplifier CS or the second amplifier CG, and source/drain doped regions SD can be formed on both sides of the gate structures G by doping, etc., and then a plurality of contact structures CT are formed on each gate structure G or the source/drain doped regions SD, wherein the contact structures CT are used for connecting the gate structures G or the source/drain doped regions SD to other elements, such as metal wire layers M1, M2, etc.

In this embodiment, a plurality of gate structures G on the left in the active area AA constitute the gate of the first amplifier CS, and a plurality of source/drain doped regions SD on the left in the active area AA constitute the source/drain of the first amplifier CS. A plurality of gate structures G on the right side in the active area AA constitute the gate of the second amplifier CG, and a plurality of source/drain doped regions SD on the right side in the active area AA constitute the source/drain of the second amplifier CG. In order to better understand the composition of the first amplifier CS and the second amplifier CG, the first source doped region S1, the second source doped region S2, the first drain doped region D1, the second drain doped region D2, the first gate structure G1 and the second gate structure G2 are defined in FIG. 4. The first source doped region S1, the second source doped region S2, the first drain doped region D1 and the second drain doped region D2 all belong to the source/drain doped region SD, while the first gate structure G1 and the second gate structure G2 belong to the gate structure G. In this embodiment, the first source doped region S1, the first drain doped region D1 and the first gate structure G1 constitute a first amplifier CS, while the second source doped region S2, the second drain doped region D2 and the second gate structure G2 constitute a second amplifier CG. In addition, there are more gate structures G and source/drain doped regions SD in the active area AA. These gate structures G and source/drain doped regions SD can be connected in parallel with the first amplifier CS or the second amplifier CG, so it is still considered that only the first amplifier CS or the second amplifier CG is connected in series in the circuit diagram. In the actual manufacturing process, the number of the gate structure G and the source/drain doped region SD can also be increased or decreased as required.

In addition, please also refer to the circuit diagram of FIG. 1, the gate CS-G of the first amplifier CS is connected to the metal wire layer M1 through the contact structure CT, and then connected to the voltage source VG1. The source CS-S of the first amplifier CS is connected to the second metal layer M2, and can be connected to the voltage source V− through the second metal layer M2. The gate CG-G of the second amplifier CG is connected to the metal conductor layer M1 through the contact structure CT, and then connected to the voltage source VG2. The drain CG-D of the second amplifier CS is connected to the second metal layer M2, and can be connected to the voltage source output signal Vout through the second metal layer M2. In this embodiment and other embodiments below, signal sources such as source S, drain D, drain CS-D of the first amplifier CS, gate CS-G of the first amplifier CS, source CS-S of the first amplifier CS, drain CG-D of the second amplifier CG, gate CG-G of the second amplifier CG, source CG-S of the second amplifier CG, voltage source VG1, voltage source VG2, etc. are directly marked on the figure. For other connection details, please refer to the circuit diagram shown in FIG. 1, and do not repeat them here.

It is worth noting that the first amplifier CS and the second amplifier CG will share a part of the source/drain doped region SD to connect the first amplifier CS and the second amplifier CG. As shown in FIG. 4, the drain CS-D of the first amplifier CS and the source CG-S of the second amplifier CG share the same source/drain doped region, that is, the source/drain doped region SD3 marked in FIG. 4. Here, the source/drain doped region SD3 can be defined as the common doped region SD3. In this embodiment, the first amplifier CS and the second amplifier CG are formed together in the same active area AA and share a part of the doped region SD3. Therefore, the distance between the first amplifier CS and the second amplifier CG can be significantly reduced.

The layout pattern shown in FIG. 4 is one embodiment of the present invention. In other embodiments of the present invention, the arrangement positions of the first amplifier CS and the second amplifier CG can also be changed in the same active area AA. For example, in FIG. 5, the first amplifier CS and the second amplifier CG are also formed in the active area AA, but in this embodiment, the second amplifier CG is located between the two first amplifiers CS, and the layout arrangement of this embodiment is similar to that shown in Figure (b) of FIG. 3. Similarly, the first amplifier CS and the second amplifier CG in this embodiment also share a part of the doped region SD3, so the advantages of reducing the device size and improving the amplifier efficiency can be achieved. Other elements or connection modes of this embodiment are similar to those of the above embodiment, so they are not repeated here.

In other embodiments, as shown in FIG. 6, the first amplifier CS and the second amplifier CG are formed in the active area AA, but in this embodiment, the first amplifier CS and the second amplifier CG are alternately and repeatedly arranged, and the layout arrangement of this embodiment is similar to that shown in the above-mentioned figure (d) of FIG. 3. Similarly, the first amplifier CS and the second amplifier CG in this embodiment also share a part of the doped region SD3, so the advantages of reducing the device size and improving the amplifier efficiency can be achieved. Other elements or connection modes of this embodiment are similar to those of the above embodiment, so they are not repeated here.

As can be seen from FIG. 4, FIG. 5 and FIG. 6, the first amplifier CS and the second amplifier CG are formed together in the same active area AA and share a part of the doped region SD3. Therefore, the distance between the first amplifier CS and the second amplifier CG will be significantly smaller than the embodiment in which the two amplifiers are formed in different active areas (for example, the embodiment on the left of FIG. 2). At the same time, because the distance between the two amplifiers is shortened, the distance between the wires is also shorter, which reduces the influence of wire impedance and improves the efficiency of the amplifiers. According to the applicant's experimental results, compared with the embodiment shown in the left half of FIG. 2, the embodiments in FIGS. 4, 5 and 6 of the present invention have reduced the area of the amplifier by more than 20% and improved the efficiency of the amplifier by more than 11%.

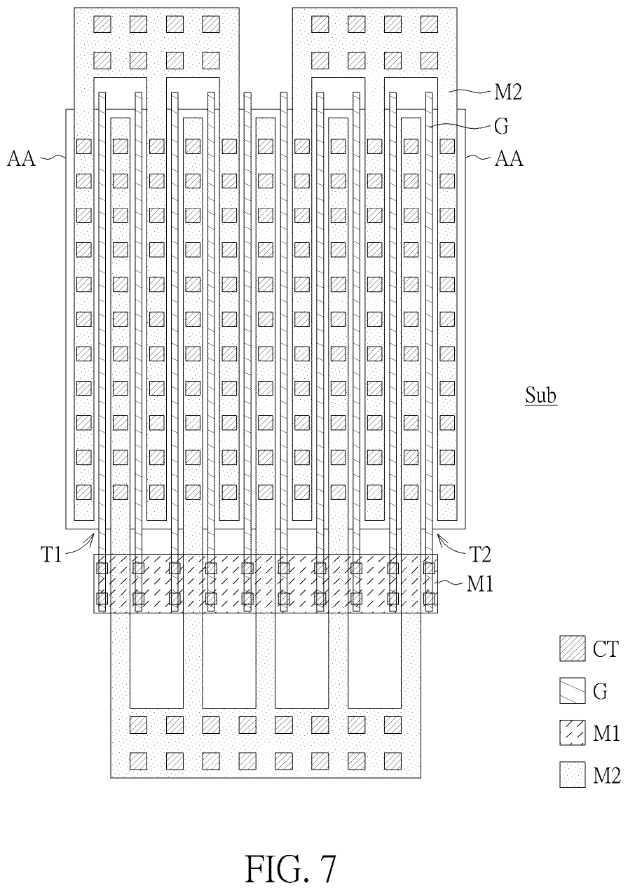

The amplifier of the present invention can also be applied to radio frequency (RF) amplifiers. FIG. 7 is a schematic diagram showing the layout of RF circuit patterns according to an embodiment of the present invention. As shown in FIG. 7, in this embodiment, most elements are similar to those in the above-mentioned FIGS. 4 to 6, such as the active area AA, the gate structures G, the contact structures CT, the metal wire layer M1 and the metal wire layer M2, etc. These same elements are denoted by the same reference numerals, and the source/drain doped regions in this embodiment are the active areas AA on both sides of the gate structure G, which are not labeled for the sake of simplicity. This embodiment proposes a layout pattern of RF amplifiers, in which a first amplifier T1 and a second amplifier T2 are included in the active area AA. The first amplifier T1 and the second amplifier T2 are connected in series with each other, and the first amplifier T1 and the second amplifier T2 are formed together in the same active area AA and share a part of the source/drain doped region. Therefore, the layout pattern applied to the RF amplifier in this embodiment also has the advantages of reducing components and improving performance. Other details about the RF amplifier belong to the known technology in this field, so I won't repeat them here.

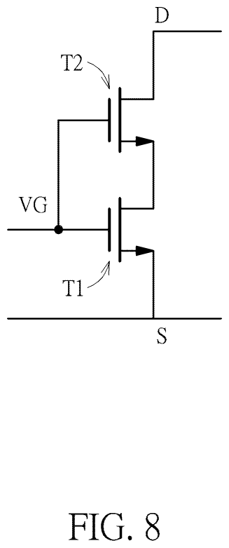

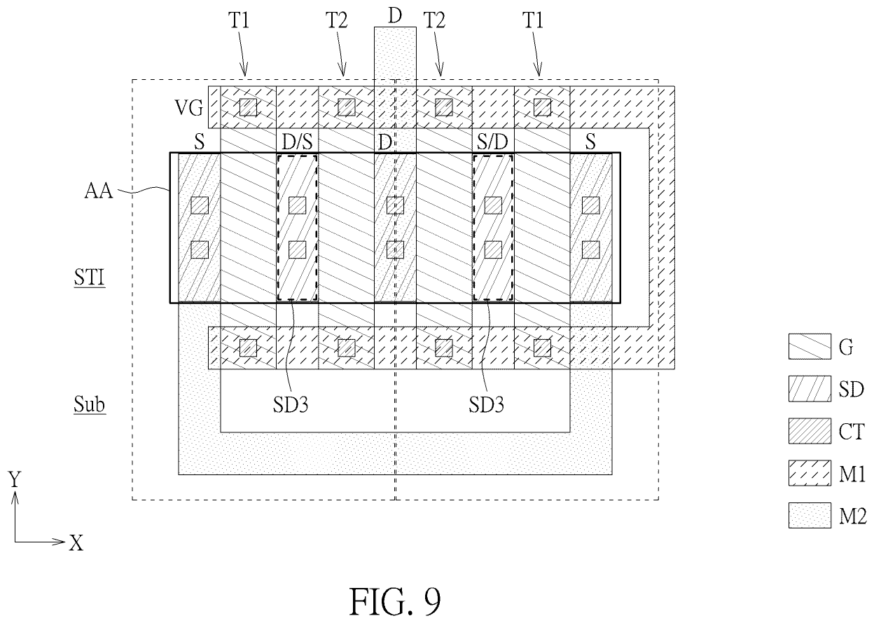

In the above embodiments, the concept of the present invention is applied to the cascade amplifier and the RF amplifier. However, as mentioned above, the concept of the present invention can also be applied to other kinds of circuits, such as the series circuit of more than two transistors. For example, FIG. 8 shows a circuit diagram of a stacked MOS metal oxide semiconductor transistor (stacked MOS), and FIG. 9 shows a layout diagram of the stacked MOS metal oxide semiconductor transistor according to an embodiment of the present invention. As shown in FIG. 8, in the circuit diagram of the stacked MOS metal oxide semiconductor transistor, the gates of the first amplifier T1 and the second amplifier T2 are connected to each other (connected to the voltage source VG), and the drain of the first amplifier T1 and the source of the second amplifier T2 are connected to each other. In the corresponding layout, please refer to FIG. 9. The active area AA includes elements such as gate structure G, source/drain doped region SD, contact structure CT, metal wire layer M1 and metal wire layer M2, and the features of these elements are the same as those in the above embodiments, so they are not repeated here. In this embodiment, the drain of the first amplifier T1 and the source of the second amplifier T2 are connected to each other and share a part of the doped region SD3, which can also achieve the effect of reducing the device size. Therefore, the invention can be applied to cascade amplifiers, RF amplifiers and other two-stage amplifiers, including stacked MOS metal oxide semiconductor transistors (stacked MOS) or Gilbert mixer, RF switch, active inductor, etc. described here, which can be applied to the scope of the invention.

Based on the above description and drawings, a semiconductor layout pattern of the present invention comprises a substrate Sub, an active area AA is defined on the substrate Sub, a plurality of gate structures G are located in the active area AA, wherein the gate structures are arranged in parallel with each other along a first direction (for example, along the X direction), and a plurality of doped regions SD are located in the active area AA, and each doped region SD is located in the substrate Sub on both sides of each gate structure G, wherein the gate structures G included in the active area AA comprise a first gate structure G1 and a second gate structure G2, and the doped regions SD included in the active area AA comprise a first source doped region S1, a first drain doped region D1, a second source doped region S2 and a second drain doped region D2. The first gate structure G1, the first source doped region S1 and the first drain doped region D1 constitute a first amplifier CS, and the second gate structure G2, the second source doped region S2 and the second drain doped region D2 constitute a second amplifier CG, wherein the first drain doped region D1 and the second source doped region S2 contain the same doped region among a plurality of doped regions, and the same doped region is defined as a common doped region SD3 (please refer to the embodiment shown in FIG. 4).

In some embodiments of the present invention, a plurality of doped regions SD are arranged in parallel with each other along a first direction (for example, X direction), and a plurality of doped regions SD and a plurality of gate structures G are alternately arranged along the first direction.

In some embodiments of the present invention, when viewed from a top view, the plurality of gate structures G and the plurality of doped regions SD are all long strips, and the long sides of the long strips SD extend along a second direction (for example, Y direction), wherein the second direction (Y direction) and the first direction (X direction) are perpendicular to each other.

In some embodiments of the present invention, from a top view, the common doped region SD3 is located between the first gate structure G1 and the second gate structure G2, and the common doped region SD3 is adjacent to the first gate structure G1 and the second gate structure G2.

In some embodiments of the present invention, the common doped region SD3 is located on one side of the first gate G1, the first source doped region S1 is located on the other side of the first gate G1 relative to the common doped region SD3, the common doped region SD3 is located on one side of the second gate G2, and the second drain doped region D2 is located on the other side of the second gate G2 relative to the common doped region SD3.

In some embodiments of the present invention, the first amplifier CS comprises a common source amplifier, the second amplifier comprises a common gate amplifier CG, and the first amplifier CS and the second amplifier CG are connected in series to form a cascade amplifier.

In some embodiments of the present invention, the first gate structure G1 is connected to a voltage source VG1 and the second drain doped region is connected to an output signal Vout.

In some embodiments of the present invention, the active area AA further includes a plurality of common source amplifiers CS and a plurality of common gate amplifiers CG, wherein each region including the common source amplifier CS is defined as a first region, and each region including the common gate amplifier CG is defined as a second region.

In some embodiments of the present invention, at least one of the plurality of first regions is located between two adjacent second regions, and at least one of the plurality of second regions is located between two adjacent first regions (for example, in Figure (d) of FIG. 3, a plurality of first regions and a plurality of second regions are alternately arranged).

In some embodiments of the present invention, there is no shallow trench isolation structure between the doped regions SD in the active area AA.

The invention also provides a radio frequency circuit layout pattern, which comprises a substrate Sub, an active area AA is defined on the substrate Sub, a plurality of gate structures G are located in the active area AA, wherein each gate structure G is arranged in parallel along a first direction (for example, X direction), and a plurality of doped regions SD are located in the active area AA, and each doped region SD is located in the substrate Sub on both sides of each gate structure G, wherein a plurality of gate structures G and a plurality of doped regions SD contained in the active area AA constitute a first amplifier CS and a second amplifier CG, wherein a drain CS-D of the first amplifier CS and a source CG-S of the second amplifier CG are connected with each other, and the drain CS-D of the first amplifier CS and the source CG-S of the second amplifier CG are both located on a common doped region SD3.

In some embodiments of the present invention, a plurality of doped regions SD are arranged in parallel with each other along a first direction (X direction), and a plurality of doped regions SD and a plurality of gate structures G are alternately arranged along the first direction.

In some embodiments of the present invention, when viewed from a top view, the gate structures G and the doped regions SD are all long strips, and the long sides of the long strips all extend along a second direction (for example, Y direction), wherein the second direction (Y direction) and the first direction (X direction) are perpendicular to each other.

In some embodiments of the present invention, the gate structures G include a first gate structure G1 and a second gate structure G2, and the doped regions SD included in the active area AA include a first source doped region S1, a first drain doped region D1, a second source doped region S2 and a second drain doped region D2. The first gate structure G1, the first source doped region S1 and the first drain doped region D1 constitute a first amplifier CS, and the second gate structure G2, the second source doped region S2 and the second drain doped region D2 constitute a second amplifier CG, wherein the first drain doped region D1 and the second source doped region S2 contain the same doped region among a plurality of doped regions SD, and the same doped region is defined as a common doped region SD3.

In some embodiments of the present invention, from a top view, the common doped region SD3 is located between the first gate structure G1 and the second gate structure G2, and the common doped region SD3 is adjacent to the first gate structure G1 and the second gate structure G2.

In some embodiments of the present invention, the common doped region SD3 is located on one side of the first gate G1, the first source doped region S1 is located on the other side of the first gate G1 relative to the common doped region SD3, the common doped region SD3 is located on one side of the second gate G2, and the second drain doped region D2 is located on the other side of the second gate G2 relative to the common doped region SD3.

In some embodiments of the present invention, the first amplifier CS comprises a common source amplifier and the second amplifier CG comprises a common gate amplifier, and the first amplifier CS and the second amplifier CG are connected in series to form a cascade amplifier.

In some embodiments of the present invention, the active area AA further includes a plurality of common source amplifiers and a plurality of common gate amplifiers, wherein each region including the common source amplifier CS is defined as a first region, and each region including the common gate amplifier CG is defined as a second region.

In some embodiments of the present invention, at least one of the plurality of first regions is located between two adjacent second regions, and at least one of the plurality of second regions is located between two adjacent first regions (for example, in Figure (d) of FIG. 3, a plurality of first regions and a plurality of second regions are alternately arranged).

In some embodiments of the present invention, there is no shallow trench isolation structure between the doped regions SD in the active area AA.

To sum up, the present invention is characterized in that, in order to save element space and reduce the influence of wire impedance when making the layout pattern of two-stage amplifier, the two amplifiers are made in the same active area, so that all the two amplifiers included in the two-stage amplifier can share a part of the doped region, that is to say, there is no shallow trench isolation between the regions where the two amplifiers are located. Under the concept of the invention, the device size can be effectively reduced, and the efficiency of the amplifier can also be improved because the influence of wire impedance is reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor layout pattern, comprising:
a substrate with an active area defined thereon;
a plurality of gate structures located in the active area, wherein the gate structures are arranged in parallel with each other along a first direction;
a plurality of doped regions located in the active area, and each doped region is located in the substrate on one of the both sides of each gate structure;
wherein the gate structures included in the active area comprise a first gate structure and a second gate structure, and the doped regions included in the active area comprise a first source doped region, a first drain doped region, a second source doped region and a second drain doped region, wherein the first gate structure, the first source doped region and the first drain doped region constitute a first amplifier, the second gate structure, the second source doped region and the second drain doped region constitute a second amplifier, and the first drain doped region and the second source doped region include a same doped region among the plurality of doped regions, and the same doped region is defined as a common doped region.

2. The semiconductor layout pattern according to claim 1, wherein the plurality of doped regions are arranged in parallel with each other along the first direction, and the plurality of doped regions and the plurality of gate structures are alternately arranged along the first direction.

3. The semiconductor layout pattern according to claim 1, wherein, when viewed from a top view, the plurality of gate structures and the plurality of doped regions are both long strips, and the long sides of the long strips extend along a second direction, wherein the second direction is perpendicular to the first direction.

4. The semiconductor layout pattern according to claim 1, wherein the common doped region is located between the first gate structure and the second gate structure, and the common doped region is located adjacent to the first gate structure and the second gate structure when viewed from a top view.

5. The semiconductor layout pattern according to claim 4, wherein the common doped region is located on one side of the first gate, the first source doped region is located on the other side of the first gate relative to the common doped region, the common doped region is located on one side of the second gate, and the second drain doped region is located on the other side of the second gate relative to the common doped region.

6. The semiconductor layout pattern according to claim 1, wherein the first amplifier comprises a common source amplifier and the second amplifier comprises a common gate amplifier, and the first amplifier and the second amplifier are connected in series to form a cascade amplifier.

7. The semiconductor layout pattern according to claim 6, wherein the first gate structure is connected to a voltage source VG1 and the second drain doped region is connected to an output signal Vout.

8. The semiconductor layout pattern according to claim 1, wherein the active area further comprises a plurality of common source amplifiers and a plurality of common gate amplifiers, wherein each region containing the common source amplifiers is defined as a first region, and each region containing the common gate amplifiers is defined as a second region.

9. The semiconductor layout pattern according to claim 8, wherein at least one of the plurality of first regions is located between two adjacent second regions, and at least one of the plurality of second regions is located between two adjacent first regions.

10. The semiconductor layout pattern according to claim 1, wherein a shallow trench isolation structure is not included between the doped regions in the active area.

11. A radio frequency (RF) circuit layout pattern, comprising:
a substrate with an active area defined thereon;
a plurality of gate structures located in the active area, wherein the gate structures are arranged in parallel with each other along a first direction;
a plurality of doped regions located in the active area, and each doped region is located in the substrate on both sides of each gate structure;
wherein the plurality of gate structures and the plurality of doped regions included in the active area constitute a first amplifier and a second amplifier, wherein a drain of the first amplifier and a source of the second amplifier are connected with each other, and both the drain of the first amplifier and the source of the second amplifier are located on a common doped region.

12. The radio frequency circuit layout pattern according to claim 11, wherein the plurality of doped regions are arranged in parallel with each other along the first direction, and the plurality of doped regions and the plurality of gate structures are alternately arranged along the first direction.

13. The radio frequency circuit layout pattern according to claim 11, wherein, when viewed from a top view, the plurality of gate structures and the plurality of doped regions are all long strips, and the long sides of the long strips extend along a second direction, wherein the second direction is perpendicular to the first direction.

14. The radio frequency circuit layout pattern according to claim 11, wherein the plurality of gate structures comprise a first gate structure and a second gate structure, and the plurality of doped regions contained in the active area comprise a first source doped region, a first drain doped region, a second source doped region and a second drain doped region, wherein the first gate structure, the first source doped region and the first drain doped region constitute the first amplifier, the second gate structure, the second source doped region and the second drain doped region constitute the second amplifier, and the first drain doped region and the second source doped region include the same doped region among the plurality of doped regions, and the same doped region is defined as the common doped region.

15. The radio frequency circuit layout pattern according to claim 14, wherein the common doped region is located between the first gate structure and the second gate structure when viewed from a top view, and the common doped region is located adjacent to the first gate structure and the second gate structure.

16. The radio frequency circuit layout pattern according to claim 15, wherein the common doped region is located on one side of the first gate, the first source doped region is located on the other side of the first gate relative to the common doped region, the common doped region is located on one side of the second gate, and the second drain doped region is located on the other side of the second gate relative to the common doped region.

17. The radio frequency circuit layout pattern according to claim 11, wherein the first amplifier comprises a common source amplifier and the second amplifier comprises a common gate amplifier, and the first amplifier and the second amplifier are connected in series to form a cascade amplifier.

18. The radio frequency circuit layout pattern according to claim 11, wherein the active area further comprises a plurality of common source amplifiers and a plurality of common gate amplifiers, wherein each region containing the common source amplifiers is defined as a first region, and each region containing the common gate amplifiers is defined as a second region.

19. The radio frequency circuit layout pattern according to claim 18, wherein at least one of the plurality of first regions is located between two adjacent second regions, and at least one of the plurality of second regions is located between two adjacent first regions.

20. The radio frequency circuit layout pattern according to claim 11, wherein a shallow trench isolation structure is not included between the doped regions in the active area.
